(19) United States
(12) Patent Application Publication
(10) Pub. No.: US 2021/0291617 A1
(43) Pub. Date: Sep. 23, 2021

(54) AMBIENT TEMPERATURE CONTROL SYSTEM AND METHOD FOR STARTUP OF IN-VEHICLE SERVER AND VEHICLE

(71) Applicants: Inventec (Pudong) Technology Corporation, Shanghai (CN); INVENTEC CORPORATION, Taipei (TW)

(72) Inventors: Debin QI, Shanghai (CN); Pinyi XIANG, Shanghai (CN); Xuefeng CHEN, Shanghai (CN); Dong-rui XUE, Shanghai (CN)

(73) Assignees: Inventec (Pudong) Technology Corporation, Shanghai (CN); INVENTEC CORPORATION, Taipei (TW)

(21) Appl. No.: 17/029,049

(22) Filed: Sep. 23, 2020

(30) Foreign Application Priority Data
Mar. 17, 2020 (CN) 2020101877548

(51) Int. Cl. B60H 1/00

(52) U.S. Cl. CPC B60H 1/00271; B60H 1/00564; B60H 1/00485; B60H 2001/00242; B60H 1/00807; B60H 2001/003; B60H 1/00207

(57) ABSTRACT

The present disclosure provides an ambient temperature control system and method for a startup of an in-vehicle server and a vehicle. The ambient temperature control system includes: a temperature detection module, disposed in an in-vehicle server, and detecting an ambient temperature of the in-vehicle server; and a temperature control module, connected with the temperature detection module, and controlling a vehicle air conditioner according to the ambient temperature detected by the temperature detection module, so as to adjust the ambient temperature of the in-vehicle server by using the vehicle air conditioner. Based on the above, in the present disclosure, an ambient temperature of the in-vehicle server is adjusted by using conditioned air of an automobile, so that the in-vehicle server is at a suitable ambient temperature, thereby ensuring a successful startup and smooth running of the in-vehicle server.

### CROSS REFERENCES TO RELATED APPLICATIONS

This application claims the benefits of priority to Chinese Patent Application No. CN 2020101877548, entitled “Ambient Temperature Control System and Method for Startup of In-Vehicle Server and Vehicle”, filed with CNIPO on Mar. 17, 2020, the contents of which are incorporated herein by reference in its entirety.

### TECHNICAL FIELD

The present disclosure relates to the field of vehicle technologies, in particular, to the field of vehicle intelligent control technologies, and specifically to an ambient temperature control system and method for a startup of an in-vehicle server and a vehicle.

### BACKGROUND

When an automobile is exposed in the external environment, a temperature inside the vehicle is affected by the external natural environment, and the temperature is low or high. A startup and running of an in-vehicle server require a suitable temperature environment. When the in-vehicle server is started, a lowest ambient temperature is generally required to be higher than 0° C.; and during running, a highest ambient temperature is required to be lower than 50° C. In this case, the ambient temperature of a space in which the in-vehicle server is located needs to be controlled and adjusted, to ensure a normal startup and smooth running of the in-vehicle server.

In winter, the external ambient temperature is usually lower than 0° C., which will affect the startup of the in-vehicle server. Especially, in a high-latitude area, the ambient temperature is usually lower than −20° C.[1], which will result in the in-vehicle server cannot be started.

In summer, the external ambient temperature is usually higher than 30° C., and the highest temperature 1 m above the road surface exceeds 40° C. (shown in FIG. 1). The automobile is exposed in the sun, the environment inside the vehicle is hermetic, and ventilation and cooling conditions are poor. Therefore, a highest temperature inside the vehicle in summer may reach 70° C. to 80° C. When an in-vehicle server inside an automobile is started and runs at an excessively high ambient temperature, the load of a heat dissipation system is increased, which may cause a running fault.

### SUMMARY

The present disclosure provides an ambient temperature control system and method for a startup of an in-vehicle server and a vehicle, to resolve the problem that a temperature of an ambient space in which an in-vehicle server is located cannot be effectively adjusted

The present disclosure provides an ambient temperature control system for a startup of an in-vehicle server, including a temperature detection module, disposed in an in-vehicle server, and detecting an ambient temperature of the in-vehicle server; and a temperature control module, connected with the temperature detection module, and controlling a vehicle air conditioner according to the ambient temperature detected by the temperature detection module, so as to adjust the ambient temperature of the in-vehicle server, by using the vehicle air conditioner.

In an embodiment of the present disclosure, the ambient temperature control system for a startup of an in-vehicle server further includes: an air conditioner duct, for the conditioned air of the vehicle air conditioner to circulate, where an air duct inlet of the air conditioner duct is configured at an air outlet of the vehicle air conditioner, to receive the conditioned air from the vehicle air conditioner; and an air duct outlet of the air conditioner duct is configured in the in-vehicle server, to blow the conditioned air to the environment in which the in-vehicle server is located, so as to adjust the ambient temperature of the in-vehicle server; and an air conditioner valve, disposed in the air duct inlet of the air conditioner duct, where opening or closing of the air conditioner valve is controlled according to the ambient temperature detected by the temperature detection module, to control whether the conditioned air of the vehicle air conditioner enters the air conditioner duct.

In an embodiment of the present disclosure, the in-vehicle server is configured in a trunk of a vehicle, and the air conditioner duct extends to the in-vehicle server through a baseplate of a carriage of the vehicle.

In an embodiment of the present disclosure, the temperature control module comprises: a first comparison unit, comparing the detected ambient temperature with a low temperature threshold, and outputting a first comparison result; a second comparison unit, comparing the detected ambient temperature with a high temperature threshold, and outputting a second comparison result; and an air conditioner control unit, separately connected with the first comparison unit and the second comparison unit, when the first comparison result is that the ambient temperature is lower than the low temperature threshold, the air conditioner control unit controls the vehicle air conditioner to be in a warm air working mode, when the second comparison result is that the ambient temperature is higher than the high temperature threshold, the air conditioner control unit controls the vehicle air conditioner to be in a cold air working mode, and controlling the vehicle air conditioner to be in an off working mode when the first comparison result is that the ambient temperature is higher than the low temperature threshold and the second comparison result is that the ambient temperature is lower than the high temperature threshold, the air conditioner control unit controls the vehicle air conditioner to be turned off.

In an embodiment of the present disclosure, the temperature control module is configured in an electronic control unit (ECU) of the vehicle.

In an embodiment of the present disclosure, the temperature detection module comprises at least one temperature sensor.

An embodiment of the present disclosure further provides a vehicle, comprising the ambient temperature control system for a startup of an in-vehicle server described above.

An embodiment of the present disclosure further provides an ambient temperature control method for a startup of an in-vehicle server, comprising: detecting an ambient temperature of an in-vehicle server; and controlling a vehicle air conditioner according to the detected ambient temperature, so as to adjust.

In an embodiment of the present disclosure, the conditioned air is blown, by using an air conditioner duct, to the environment in which the in-vehicle server is located, and whether the conditioned air of the vehicle air conditioner enters the air conditioner duct is controlled by controlling opening or closing of an air conditioner valve, to adjust the ambient temperature of the in-vehicle server.

In an embodiment of the present disclosure, the controlling of, a vehicle air conditioner according to the detected ambient temperature includes: separately comparing the detected ambient temperature with a low temperature threshold and a high temperature threshold; controlling the vehicle air conditioner to be in a warm air working mode if the ambient temperature is lower than the low temperature threshold; controlling the vehicle air conditioner to be in a cold air working mode if the ambient temperature is higher than the high temperature threshold; and controlling the vehicle air conditioner to be in an off working mode if the ambient temperature is higher than the low temperature threshold and lower than the high temperature threshold.

As described above, the ambient temperature control system and method for a startup of an in-vehicle server and the vehicle consistent with the present disclosure have the following beneficial effect:

In the present disclosure, an ambient temperature of a space in which an in-vehicle server is located is adjusted by using conditioned air of an automobile, so that the in-vehicle server is at a suitable ambient temperature, thereby ensuring a successful startup and smooth running of the in-vehicle server.

### BRIEF DESCRIPTION OF THE DRAWINGS

FIG. 1 is a block diagram of a principle of an ambient temperature control system for a startup of an in-vehicle server according to an embodiment of the present disclosure.

FIG. 2 is a block diagram of a principle of an ambient temperature control system for a startup of an in-vehicle server according to another embodiment of the present disclosure.

FIG. 3 is a block diagram of a principle of a temperature control module according to another embodiment of the present disclosure.

FIG. 4 is a side view of installation positions of an in-vehicle server and an air conditioner duct according to an embodiment of the present disclosure.

FIG. 5 is a front view of installation positions of an in-vehicle server and an air conditioner duct according to an embodiment of the present disclosure.

FIG. 6 is a schematic flowchart of an example of an ambient temperature control method for a startup of an in-vehicle server according to an embodiment of the present disclosure.

FIG. 7 is a schematic flowchart of an ambient temperature control method for a startup of an in-vehicle server according to an embodiment of the present disclosure.

FIG. 8 is a curve graph of test data of ambient temperature control for a startup of an in-vehicle server according to an embodiment of the present disclosure.

### DESCRIPTION OF REFERENCE NUMERALS

100 Ambient temperature control system for a startup of an in-vehicle server
110 Temperature detection module
120 Temperature control module
121 First comparison unit
122 Second comparison unit
123 Air conditioner control unit
130 Air conditioner duct
140 Air conditioner valve
200 in-vehicle server
300 Vehicle air conditioner

### DETAILED DESCRIPTION OF THE PREFERRED EMBODIMENTS

Implementations of the present disclosure are described below by using specific examples. A person skilled in the art can easily understand other advantages and effects of the present disclosure from the content disclosed in this specification. The present disclosure may also be implemented or applied through other different specific implementations. Various details in this specification may also be modified or changed based on different viewpoints and applications without departing from the spirit of the present disclosure.

Referring to FIGS. 1 to 8, it should be understood that all the structures, proportions, sizes, and the like depicted in the accompanying drawings of this specification are merely used for matching the content disclosed in this specification, for those skilled in the art to learn and read, but are not intended to limit restraint conditions under which the present disclosure can be implemented, therefore having no substantial meaning technically. Any modification of the structures, change of proportion relationships, or adjustment of the sizes shall fall within the scope of the technical content disclosed in the present disclosure without affecting the effects that can be generated and the objectives that can be achieved through the present disclosure.

In addition, the terms such as “upper”, “lower’, “left”, “right”, “middle”, and “a” mentioned in this specification are also merely for facilitating clear descriptions, but are not intended to limit the scope of implementation of the present disclosure. Without substantially changing the technical contents, changes or adjustments of relative relationships thereof should also fall within the scope of implementation of the present disclosure.

The present disclosure provides an ambient temperature control system and method for a startup of an in-vehicle server and a vehicle, to resolve the problem that a temperature of an ambient space in which an in-vehicle server is located cannot be effectively adjusted.

Principles and implementations of the ambient temperature control system, method and the vehicle for a startup of an in-vehicle server of the embodiments are to be described below in detail, so that a person skilled in the art can understand the ambient temperature control system and method for a startup of an in-vehicle server and the vehicle of the embodiments without creative efforts.

### Embodiment 1

As shown in FIG. 1, this embodiment provides an ambient temperature control system 100 for a startup of an in-vehicle server. The ambient temperature control system 100 for a startup of an in-vehicle server includes: a temperature detection module 110 and a temperature control module 120.

The ambient temperature control system 100 for a startup of an in-vehicle server 200 of a vehicle in this embodiment is described below in detail.

In this embodiment, the temperature detection module 110 is disposed in the in-vehicle server 200, and is configured to detect an ambient temperature of the in-vehicle server 200.

In this embodiment, the temperature detection module 110 includes at least one temperature sensor.

The temperature sensor in this embodiment includes, but is not limited to, a thermocouple temperature sensor, a thermistor temperature sensor, and the like. The type of the temperature sensor is not specifically limited in this embodiment.

There may be one or more temperature sensors. In this embodiment, the number of the temperature sensors is not specifically limited, and may be configured by a person skilled in the art according to an actual requirement.

The temperature sensor is disposed beside the in-vehicle server 200, to help detect the ambient temperature of the in-vehicle server 200.

In this embodiment, the temperature control module 120 is connected to the temperature detection module 110, and is configured to control, according to the ambient temperature detected by the temperature detection module 110, a vehicle air conditioner 300, so as to adjust the ambient temperature of the in-vehicle server 200.

The temperature control module 120 is configured in an ECU of the vehicle, and is a functional module or program control module in the ECU of the vehicle. An ambient temperature of the in-vehicle server 200 is detected by using the temperature sensor, and is fed back to the ECU of the vehicle. The ECU determines whether the detected ambient temperature is suitable, whether the vehicle air conditioner 300 needs to be turned on, a specific working mode of the vehicle air conditioner 300, and the like.

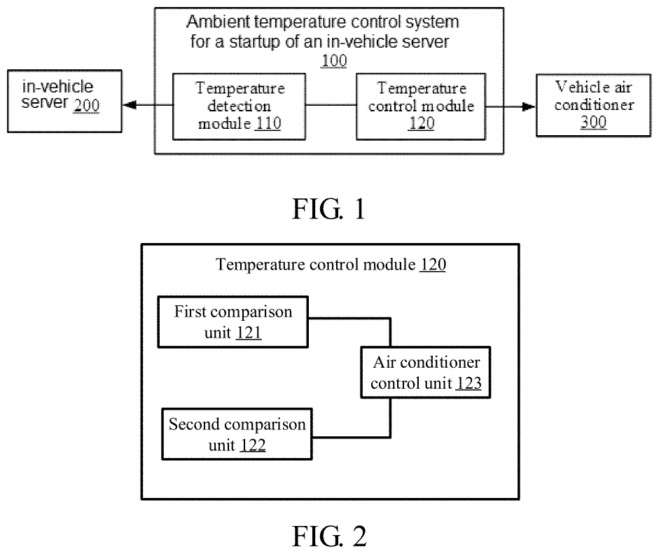

Specifically, as shown in FIG. 2, in this embodiment, the temperature control module 120 includes: a first comparison unit 121, a second comparison unit 122, and an air conditioner control unit 123.

In this embodiment, the first comparison unit 121 compares the detected ambient temperature with a low temperature threshold, and output a first comparison result. The first comparison result is a first result value or a second result value. For example, the first result value is 1, and the second result value is 0, which respectively represent that the ambient temperature is higher than a low temperature threshold and the ambient temperature is lower than or equal to the low temperature threshold. For example, when the ambient temperature is higher than the low temperature threshold, the first comparison result is the first result value, and when the ambient temperature is lower than the low temperature threshold, the first comparison result is the second result value.

In this embodiment, the second comparison unit 122 is configured to compare the detected ambient temperature with a high temperature threshold, and output a second comparison result. The second comparison result is a third result value or a fourth result value. For example, the third result value is 1, and the fourth result value is 0, which respectively represent that the ambient temperature is higher than or equal to a high temperature threshold and the ambient temperature is lower than the high temperature threshold. For example, when the ambient temperature is higher than the high temperature threshold, the second comparison result is the third result value, and when the ambient temperature is lower than the high temperature threshold, the second comparison result is the fourth result value.

In this embodiment, the air conditioner control unit 123 is separately connected to the first comparison unit 121 and the second comparison unit 122. when the first comparison result is that the ambient temperature is lower than the low temperature threshold, the air conditioner control unit 123 controls the vehicle air conditioner 300 to be in a warm air working mode, when the second comparison result is that the ambient temperature is higher than the high temperature threshold, the air conditioner control unit 123 controls the vehicle air conditioner 300 to be in a cold air working mode, and when the first comparison result is that the ambient temperature is higher than the low temperature threshold and the second comparison result is that the ambient temperature is lower than the high temperature threshold, the air conditioner control unit 123 controls the vehicle air conditioner 300 to be turned off.

The low temperature threshold and the high temperature threshold may be set according to a normal running temperature of the in-vehicle server 200. The low temperature threshold and the high temperature threshold match a temperature range required by a startup of the in-vehicle server 200, and are as close to the ambient temperature as possible, to reduce energy consumption while ensuring a temperature for a normal startup of the in-vehicle server 200. For example, the low temperature threshold is 0° C., and the high temperature threshold is 50° C.

That is, in this embodiment, when the ambient temperature of the in-vehicle server 200 is excessively low, the vehicle air conditioner 300 is controlled to blow warm air to the environment of the in-vehicle server 200; and when the ambient temperature of the in-vehicle server 200 is excessively high, the vehicle air conditioner 300 is controlled to blow cold air to the environment of the in-vehicle server 200, thereby implementing control of the ambient temperature of the in-vehicle server 200.

Therefore, in the ambient temperature control system 100 for the startup of the in-vehicle server 200 of the vehicle in this embodiment, the ambient temperature of the in-vehicle server 200 is adjusted by using conditioned air of the automobile, so that the in-vehicle server 200 is at a suitable ambient temperature, thereby ensuring a successful startup and smooth running of the in-vehicle server 200.

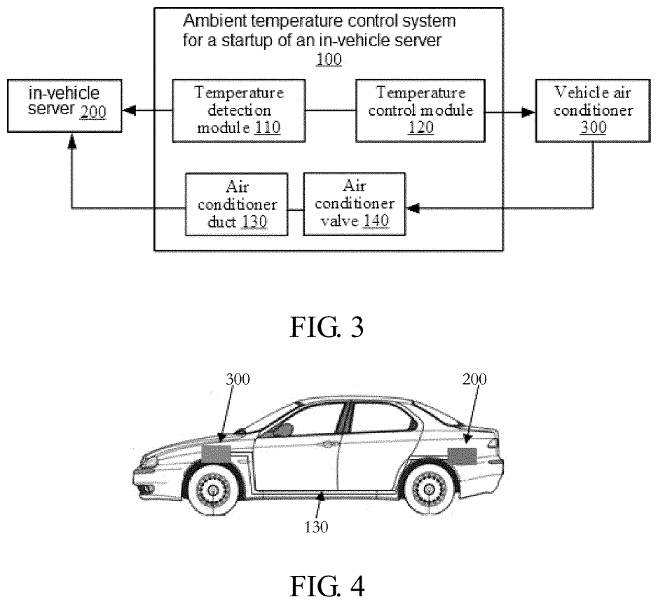

In this embodiment, the in-vehicle server 200 is configured in a trunk of the vehicle. In this case, as shown in FIG. 3, the ambient temperature control system 100 for the startup of the in-vehicle server 200 of the vehicle in this embodiment further includes: an air conditioner duct 130 and an air conditioner valve 140.

When the in-vehicle server 200 is configured in the trunk of the vehicle, an air conditioner duct 130 for heat dissipation of the in-vehicle server 200 is added based on an original air conditioner duct of the automobile.

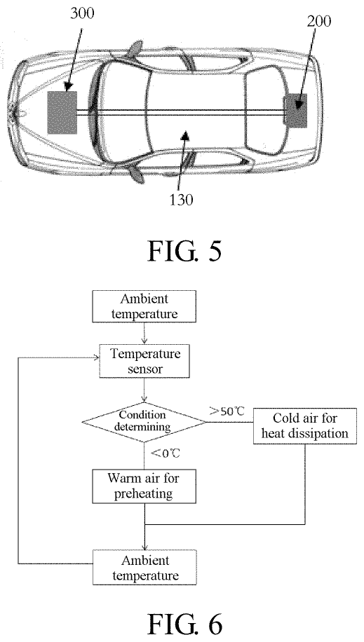

As shown in FIG. 4 and FIG. 5, the air conditioner duct 130 extends to the in-vehicle server 200 through a baseplate of the trunk of the vehicle. That is, when the in-vehicle server 200 is placed at the bottom of the trunk of the automobile, the added air conditioner duct 130 in the automobile connects the in-vehicle server 200 and the automobile air conditioner in the front of the automobile by passing through the baseplate of the trunk.

In this case, the temperature sensor is preferably disposed in the air conditioner duct 130, for example, in an air duct outlet of the air conditioner duct 130.

Specifically, in this embodiment, the air conditioner duct 130 is configured for the conditioned air of the vehicle air conditioner 300 to circulate; an air duct inlet of the air conditioner duct 130 is configured at an air outlet of the vehicle air conditioner 300, to receive the conditioned air from the vehicle air conditioner 300. The air duct outlet of the air conditioner duct 130 is configured in the in-vehicle server 200, to blow the received conditioned air to the environment in which the in-vehicle server 200 is located, so as to adjust the ambient temperature of the in-vehicle server 200.

In this embodiment, the air conditioner valve 140 is disposed in the air duct inlet of the air conditioner duct 130. The opening or closing of the air conditioner valve 140 is controlled according to the ambient temperature detected by the temperature detection module 110, to control whether the conditioned air of the vehicle air conditioner 300 enters the air conditioner duct 130.

Therefore, in this embodiment, when the in-vehicle server 200 is far away from an original air outlet of the vehicle air conditioner, conditioned air is blown to the environment in which the in-vehicle server 200 is located by using the added air conditioner duct 130 and the air conditioner valve 140. When the ambient temperature of the in-vehicle server 200 is excessively high, cold air is blown to the environment in which the in-vehicle server 200 is located; and when the ambient temperature of the in-vehicle server 200 is excessively low, hot air is blown to the environment in which the in-vehicle server 200 is located, to adjust the ambient temperature of the in-vehicle server 200.

As shown in FIG. 6, to make a person skilled in the art to further understand the principle and implementations of this embodiment, the principle and working process of the ambient temperature control system 100 for the startup of the in-vehicle server of the vehicle are described below by using an example.

In this embodiment, the ambient temperature of a space in which the in-vehicle server 200 is located is adjusted by using the conditioned air of the automobile.

When the in-vehicle server 200 is not started, the ambient temperature of the in-vehicle server 200 is detected by using the temperature sensor, and is fed back to the ECU of the vehicle. The ECU of the vehicle determines whether the temperature is in a set control range, and for example, if the temperature is lower than 0° C., an air supply valve of the automobile air conditioner is open, to blow warm air for preheating; and if the temperature is higher than 50° C., the air supply valve of the automobile air conditioner is open, to blow cold air for heat dissipation. By repetition in such a way, control of the ambient temperature of the in-vehicle server 200 is implemented, so that the ambient temperature of the in-vehicle server 200 is maintained at 0° C. to 50° C., thereby ensuring that the in-vehicle server 200 can be normally started in an extreme temperature environment.

In addition, this embodiment further provides a vehicle, comprising the ambient temperature control system 100 for a startup of an in-vehicle server described above. The ambient temperature control system 100 for a startup of an in-vehicle server is specifically described above, and details are not described herein again.

### Embodiment 2

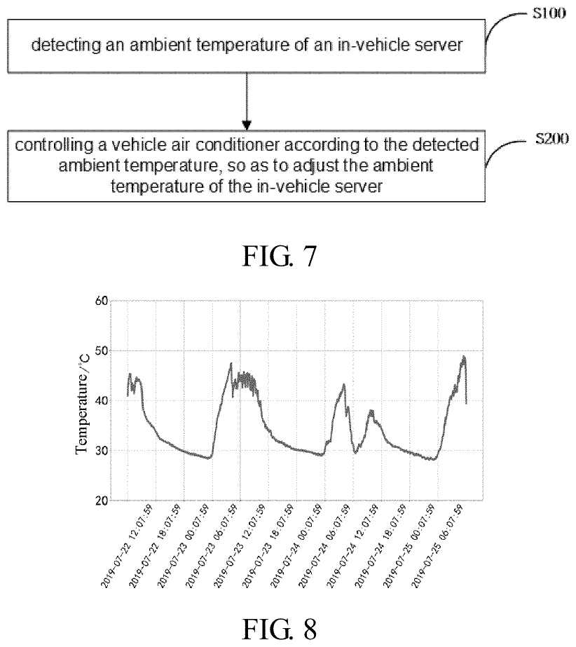

As shown in FIG. 7, this embodiment of the present disclosure further provides an ambient temperature control method for a startup of an in-vehicle server, comprising the following steps:

Step S100: Detecting an ambient temperature of an in-vehicle server.

Step S200: Controlling a vehicle air conditioner according to the detected ambient temperature, so as to adjust the ambient temperature of the in-vehicle server

In this embodiment, an implementation of the controlling a vehicle air conditioner according to the detected ambient temperature includes:

separately comparing the detected ambient temperature with a low temperature threshold and a high temperature threshold; controlling the vehicle air conditioner to be in a warm air working mode if the ambient temperature is lower than the low temperature threshold; controlling the vehicle air conditioner to be in a cold air working mode if the ambient temperature is higher than the high temperature threshold; and controlling the vehicle air conditioner to be in an off working mode if the ambient temperature is higher than the low temperature threshold and lower than the high temperature threshold.

The low temperature threshold and the high temperature threshold may be set according to a normal running temperature of the in-vehicle server. The low temperature threshold and the high temperature threshold match a temperature range required by a startup of the in-vehicle server, and are as close to the ambient temperature as possible, to reduce energy consumption while ensuring a temperature for a normal startup of the in-vehicle server. For example, the low temperature threshold is 0° C., and the high temperature threshold is 50° C.

That is, in this embodiment, when the ambient temperature of the in-vehicle server is excessively low, the vehicle air conditioner is controlled to blow warm air to the environment in which the in-vehicle server is located; and when the ambient temperature of the in-vehicle server is excessively high, the vehicle air conditioner is controlled to blow cold air to the environment in which the in-vehicle server is located, thereby implementing control of the ambient temperature of the in-vehicle server.

Therefore, in the ambient temperature control system for a startup of an in-vehicle server in this embodiment, the ambient temperature of a space in which the in-vehicle server is located is adjusted by using conditioned air of the automobile, so that the in-vehicle server is at a suitable ambient temperature, thereby ensuring a successful startup and smooth running of the in-vehicle server.

In this embodiment, the ambient temperature of a space in which the in-vehicle server is located is adjusted by using the conditioned air of the automobile.

When the in-vehicle server is not started, the ambient temperature at a position of the in-vehicle server is detected by using a temperature sensor, and is fed back to an ECU of the vehicle. The ECU of the vehicle determines whether the temperature is in a set control range, and for example, if the temperature is lower than 0° C., an air supply valve of the automobile air conditioner is open, to blow warm air for preheating; and if the temperature is higher than 50° C., the air supply valve of the automobile air conditioner is open, to blow cold air for heat dissipation. By repetition in such a way, control of the ambient temperature of the in-vehicle server is implemented, so that the ambient temperature of the in-vehicle server is maintained in the range from 0° C. to 50° C., thereby ensuring that the in-vehicle server can be normally started in an extreme temperature environment. Test data is shown in FIG. 8.

In this embodiment, the conditioned air is blown, by using an air conditioner duct, to the environment in which the in-vehicle server is located, and whether the conditioned air of the vehicle air conditioner enters the air conditioner duct is controlled by controlling opening or closing of an air conditioner valve, to adjust the ambient temperature of the in-vehicle server.

When the in-vehicle server is configured in the trunk of the vehicle, an air conditioner duct for heat dissipation of the in-vehicle server is added based on an original air conditioner duct of the automobile.

As shown in FIG. 4 and FIG. 5, the air conditioner duct 130 extends to the in-vehicle server 200 through a baseplate of the trunk of the vehicle. That is, when the in-vehicle server 200 is placed at the bottom of the trunk of the automobile, the added air conditioner duct 130 in the automobile connects the in-vehicle server 200 and the automobile air conditioner in the front of the automobile by passing through the baseplate of the trunk.

In this case, the temperature sensor detecting the ambient temperature of the in-vehicle server 200 is preferably disposed in the air conditioner duct 130. For example, the temperature sensor is disposed in an air duct outlet of the air conditioner duct 130.

Specifically, in this embodiment, the air conditioner duct 130 is configured for the conditioned air of the vehicle air conditioner 300 to circulate; an air duct inlet of the air conditioner duct 130 is configured at an air outlet of the vehicle air conditioner 300, to receive the conditioned air from the vehicle air conditioner 300. The air duct outlet of the air conditioner duct 130 is configured in the in-vehicle server 200, to blow the received conditioned air to the environment in which the in-vehicle server 200 is located, so as to adjust the ambient temperature of the in-vehicle server 200.

In this embodiment, the air conditioner valve 140 is disposed in the air duct inlet of the air conditioner duct 130. The opening or closing of the air conditioner valve 140 is controlled according to the detected ambient temperature, to control whether the conditioned air of the vehicle air conditioner 300 enters the air conditioner duct 130.

Therefore, in this embodiment, when the in-vehicle server 200 is far away from an original air outlet of the vehicle air conditioner, conditioned air is blown to the environment in which the in-vehicle server 200 is located by using the added air conditioner duct 130 and the air conditioner valve 140. When the ambient temperature of the in-vehicle server 200 is excessively high, cold air is blown to the environment in which the in-vehicle server 200 is located; and when the ambient temperature of the in-vehicle server 200 is excessively low, hot air is blown to the environment in which the in-vehicle server 200 is located, to adjust the ambient temperature of the in-vehicle server 200.

The ambient temperature control method for a startup of an in-vehicle server in this embodiment corresponds to the ambient temperature control system 100 for a startup of an in-vehicle server in Embodiment 1. The parts of common use between the embodiments are not described herein again.

In addition, to highlight the creative parts of the present disclosure, technical features not closely related to resolving the technical problems proposed in the present disclosure are not introduced in this embodiment, but this does not mean that no other structures and function features exist in this embodiment.

It should be noted that the drawings provided in this embodiment only exemplify the basic idea of the present disclosure. Therefore, only the components related to the present disclosure are shown in the drawings, and are not drawn according to the quantities, shapes, and sizes of the components during actual implementation. During actual implementation, the types, quantities, and proportions of the components may be randomly changed, and the layout pattern of the components may be more complicated.

Based on the above, in the present disclosure, an ambient temperature of a space in which an in-vehicle server is located is adjusted by using conditioned air of an automobile, so that the in-vehicle server is at a suitable ambient temperature, thereby ensuring a successful startup and smooth running of the in-vehicle server. Therefore, the present disclosure effectively overcomes various defects in the prior art, and has great value in industrial use.

The foregoing embodiments merely exemplarily describe the principles and effects of the present disclosure, and are not intended to limit the present disclosure. Any person skilled in the art may make modifications or changes on the foregoing embodiments without departing from the spirit and scope of the present disclosure. Therefore, any equivalent modifications or changes completed by a person of ordinary skill in the art without departing from the spirit and technical concept disclosed in the present disclosure should fall within the scope of claims of the present disclosure.

What is claimed is:

1. An ambient temperature control system for a startup of an in-vehicle server, comprising:
a temperature detection module, disposed in an in-vehicle server, and detecting an ambient temperature of the in-vehicle server; and
a temperature control module, connected with the temperature detection module, and controlling a vehicle air conditioner according to the ambient temperature detected by the temperature detection module, so as to adjust the ambient temperature of the in-vehicle server by using the vehicle air conditioner.

2. The ambient temperature control system for a startup of an in-vehicle server according to claim 1, further comprising:
an air conditioner duct, for the conditioned air of the vehicle air conditioner to circulate, wherein an air duct inlet of the air conditioner duct is configured at an air outlet of the vehicle air conditioner, to receive the conditioned air from the vehicle air conditioner; and an air duct outlet of the air conditioner duct is configured in the in-vehicle server, to blow the conditioned air to an environment in which the in-vehicle server is located, so as to adjust the ambient temperature of the in-vehicle server; and
an air conditioner valve, disposed in the air duct inlet of the air conditioner duct, wherein opening or closing of the air conditioner valve is controlled according to the ambient temperature detected by the temperature detection module, to control whether the conditioned air of the vehicle air conditioner enters the air conditioner duct.

3. The ambient temperature control system for a startup of an in-vehicle server according to claim 2, wherein the in-vehicle server is configured in a trunk of a vehicle, and the air conditioner duct extends to the in-vehicle server through a baseplate of a carriage of the vehicle.

4. The ambient temperature control system for a startup of an in-vehicle server according to claim 1, wherein the temperature control module comprises:
a first comparison unit, comparing the detected ambient temperature with a low temperature threshold, and outputting a first comparison result;
a second comparison unit, comparing the detected ambient temperature with a high temperature threshold, and outputting a second comparison result; and
an air conditioner control unit, separately connected with the first comparison unit and the second comparison unit, wherein when the first comparison result is that the ambient temperature is lower than the low temperature threshold, the air conditioner control unit controls the vehicle air conditioner to be in a warm air working mode, when the second comparison result is that the ambient temperature is higher than the high temperature threshold, the air conditioner control unit controls the vehicle air conditioner to be in a cold air working mode, and controlling the vehicle air conditioner to be in an off working mode when the first comparison result is that the ambient temperature is higher than the low temperature threshold and the second comparison result is that the ambient temperature is lower than the high temperature threshold, the air conditioner control unit controls the vehicle air conditioner to be turned off.

5. The ambient temperature control system for a startup of an in-vehicle server according to claim 4, wherein the temperature control module is configured in an electronic control unit (ECU) of the vehicle.

6. The ambient temperature control system for a startup of an in-vehicle server according to claim 1, wherein the temperature detection module comprises at least one temperature sensor.

7. A vehicle, comprising the ambient temperature control system for a startup of an in-vehicle server according to claim 1.

8. An ambient temperature control method for a startup of an in-vehicle server, comprising:
detecting an ambient temperature of an in-vehicle server; and
controlling a vehicle air conditioner according to the detected ambient temperature, so as to adjust the ambient temperature of the in-vehicle server.

9. The ambient temperature control method for a startup of an in-vehicle server according to claim 8, wherein the conditioned air is blown, by using an air conditioner duct, to an environment in which the in-vehicle server is located, and whether the conditioned air of the vehicle air conditioner enters the air conditioner duct is controlled by controlling opening or closing of an air conditioner valve, to adjust the ambient temperature of the in-vehicle server.

10. The ambient temperature control method for a startup of an in-vehicle server according to claim 8, wherein the controlling of a vehicle air conditioner according to the detected ambient temperature comprises:
separately comparing the detected ambient temperature with a low temperature threshold and a high temperature threshold; controlling the vehicle air conditioner to be in a warm air working mode if the ambient temperature is lower than the low temperature threshold; controlling the vehicle air conditioner to be in a cold air working mode if the ambient temperature is higher than the high temperature threshold; and controlling the vehicle air conditioner to be in an off working mode if the ambient temperature is higher than the low temperature threshold and lower than the high temperature threshold.
